(19) United States
(12) Patent Application Publication
(10) Pub. No.: US 2008/0290414 A1
(43) Pub. Date: Nov. 27, 2008

(54) INTEGRATING STRAIN ENGINEERING TO MAXIMIZE SYSTEM-ON-A-CHIP PERFORMANCE

(75) Inventors: Weize Xiong, Austin, TX (US); Cloves Rinn Cleavelin, Dallas, TX (US)

Correspondence Address: TEXAS INSTRUMENTS INCORPORATED, P O BOX 655474, M/S 3999, DALLAS, TX, 75265, US

(73) Assignee: Texas Instruments Incorporated, Dallas, TX (US)

(21) Appl. No.: 11/753,241

(22) Filed: May 24, 2007

(51) Int. Cl. H01L 31/036; H01L 21/336; H01L 27/01

(52) U.S. Cl. 257/348; 257/627; 438/299; 257/E21.409; 257/E31.04; 257/E27.114

(57) ABSTRACT

A semiconductor device comprising a first transistor device and second transistor device both on a semiconductor substrate. The first transistor device has a first n-channel and a first p-channel and the second transistor device has a second n-channel and a second p-channel. Each of the p-channels and the n-channels have a long lateral axis that is aligned with a orientation plane of a silicon layer of the semiconductor substrate. The second p-channel and the first and second n-channels include the silicon layer configured as strained silicon. The first p-channel includes the silicon layer configured as relaxed silicon. Each of the n-channels contact gate structures that impart a tensile stress in the n-channels.

### TECHNICAL FIELD

The disclosure is directed, in general, to semiconductor devices and their method of manufacture.

### BACKGROUND

There is a push in the semiconductor industry to manufacture system-on-a-chip (SoC), where all of the electronic components for an end-product semiconductor device are integrated on a single chip. Such SoCs can include field effect transistors (FET) that perform specialized applications. E.g., FETs such as n-type metal oxide semiconductor (nMOS) or p-type metal oxide semiconductor (pMOS) transistors that perform logic or memory operations.

### SUMMARY

The disclosure provides a semiconductor device that comprises a first transistor device and second transistor device both on a semiconductor substrate. The first transistor device has a first n-channel and a first p-channel and the second transistor device has a second n-channel and a second p-channel. Each of the p-channels and the n-channels and have a long lateral axis that is aligned with a (110) orientation plane of a silicon layer of the semiconductor substrate. The second p-channel and the first and second n-channels include a silicon layer configured as strained silicon. The first p-channel includes the silicon layer configured as relaxed silicon. Each of the n-channels contact gate structures that impart a tensile stress in the n-channels.

In another embodiment, the semiconductor device comprises a first multi-gate device having the above-described first n- and p-channels, and a second multi-gate device having the above-described second n- and p-channels. Each of the p- and n-channels and have a long lateral axis that is aligned with a (110) orientation plane of a patterned silicon layer of the semiconductor substrate that is configured as fins. The semiconductor device also comprises insulating layers located over the first and second multi-gate devices, and interconnects in or on the insulating layers, the interconnects contacting the first and second multi-gate devices.

Another aspect of the disclosure is a method of manufacturing the semiconductor device. The method comprises forming nMOS and pMOS transistors of first and second transistor devices. In such embodiments, forming the transistors includes forming a strained silicon layer on a semiconductor substrate and forming n-channels and p-channels of the nMOS and pMOS transistors from said strained silicon layer. The channels are formed such that a long lateral axis of the channels is aligned with a (110) orientation plane of the strained silicon layer. Forming the transistors also includes converting a portion of the strained silicon layer for the p-channels of the first transistor device to a relaxed silicon layer. The p-channels of the second transistor device and the n-channels of the first and second transistor devices include a remaining portion of the strained silicon layer. Forming the transistors further includes forming gate structures on each of the n-channels and p-channels. The gate structures impart a tensile stress in the n-channels.

In another embodiment, the method of manufacturing the semiconductor device comprises forming the above-described nMOS and pMOS transistors of first and second multi-gate devices. In such embodiments, forming the transistors includes patterning the strained silicon layer to form n-channels and p-channels of the nMOS and said pMOS transistors that are configured as fins. Again a long lateral axis of the channels is aligned with a (110) orientation plane of the strained silicon layer. Manufacturing the semiconductor device also comprises forming insulating layers over the first and second transistor devices and forming interconnects in or on the insulating layers, the interconnects contacting the first and second multi-gate devices.

### BRIEF DESCRIPTION OF DRAWINGS

The disclosure is described with reference to example embodiments and to accompanying drawings, wherein:

FIGS. 1 and 2A-2B illustrate plan and cross-sectional views of an example semiconductor device of the disclosure that comprises multi-gate transistors;

FIG. 3 presents a perspective view of an example semiconductor device of the disclosure that comprises single-gate planar transistors; and

FIGS. 4 to 8B illustrate cross-section views of selected steps in an example method of manufacturing a semiconductor device of the disclosure.

### DETAILED DESCRIPTION

For ease of fabrication and uniformity of transistor characteristics, all of the FETS (e.g., all nMOS and pMOS transistors) in a conventional SoC are designed to be the same. That is, all of the nMOS transistors have the same electron mobility as each other and all of the PMOS transistors have the same hole mobility as each other. This design, however, can compromise the performance of FETs that are intended for specialized applications. The semiconductor devices of the disclosure, and their method of manufacture, have had their channel regions strain-engineered to optimize their majority carrier's (e.g., holes or electron) mobility for specialized applications. That is, the individual channels have mobilities whose values, or values relative to each other, depend upon on the FET's intended application. By optimizing the carrier mobility of FETs designated for particular applications, the performance of SoCs can be improved as compared to conventional SoCs.

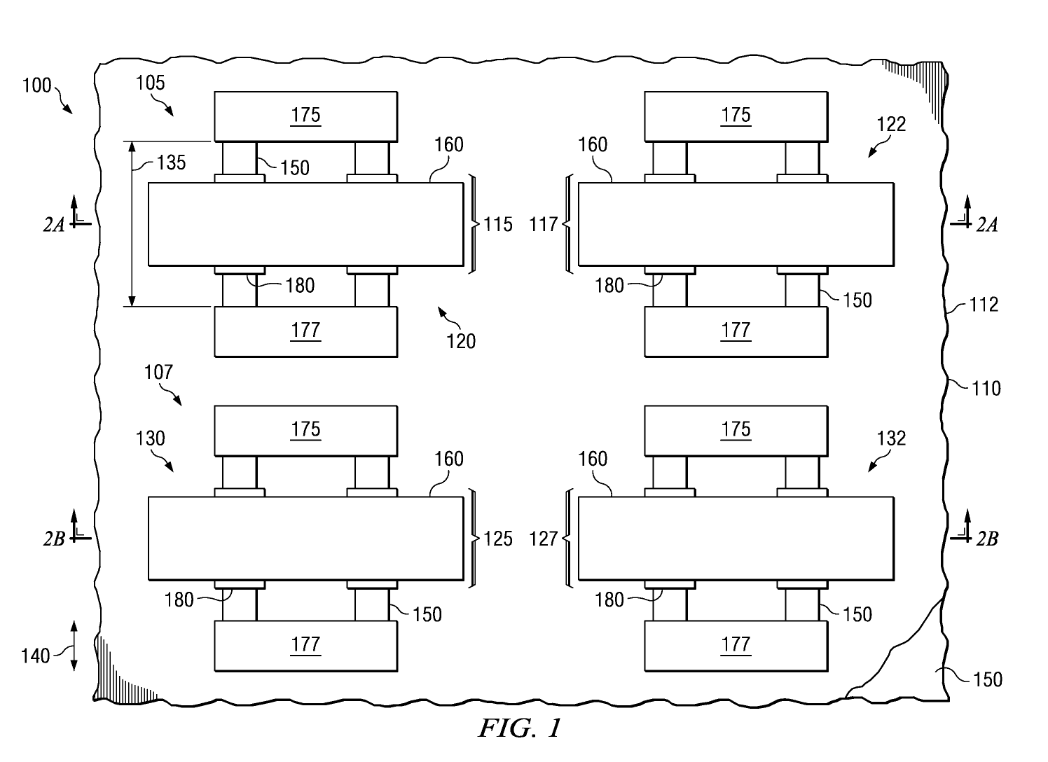

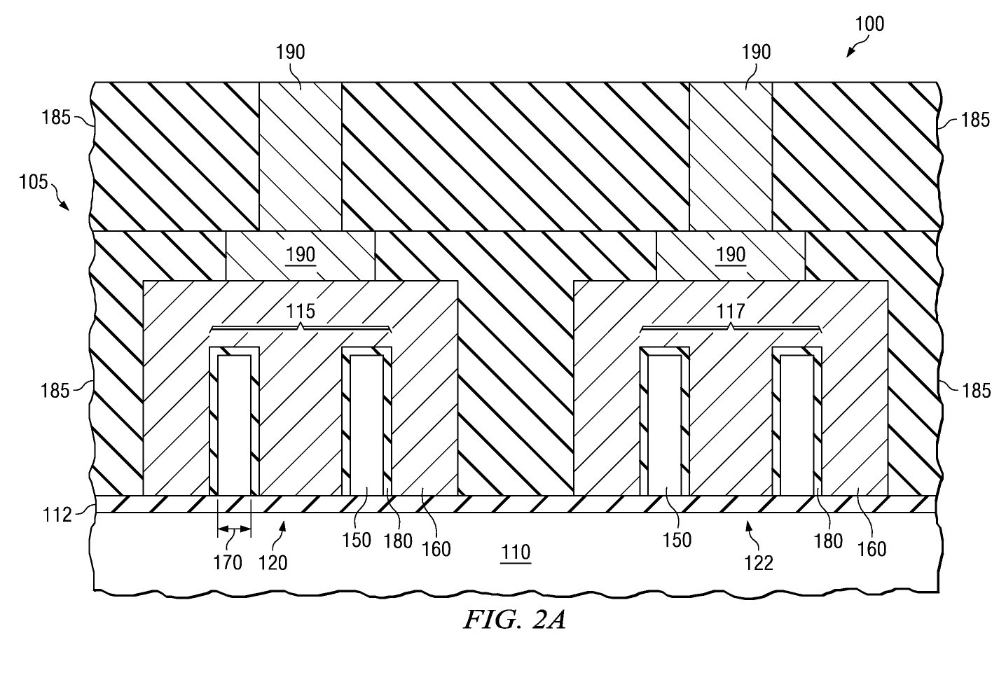

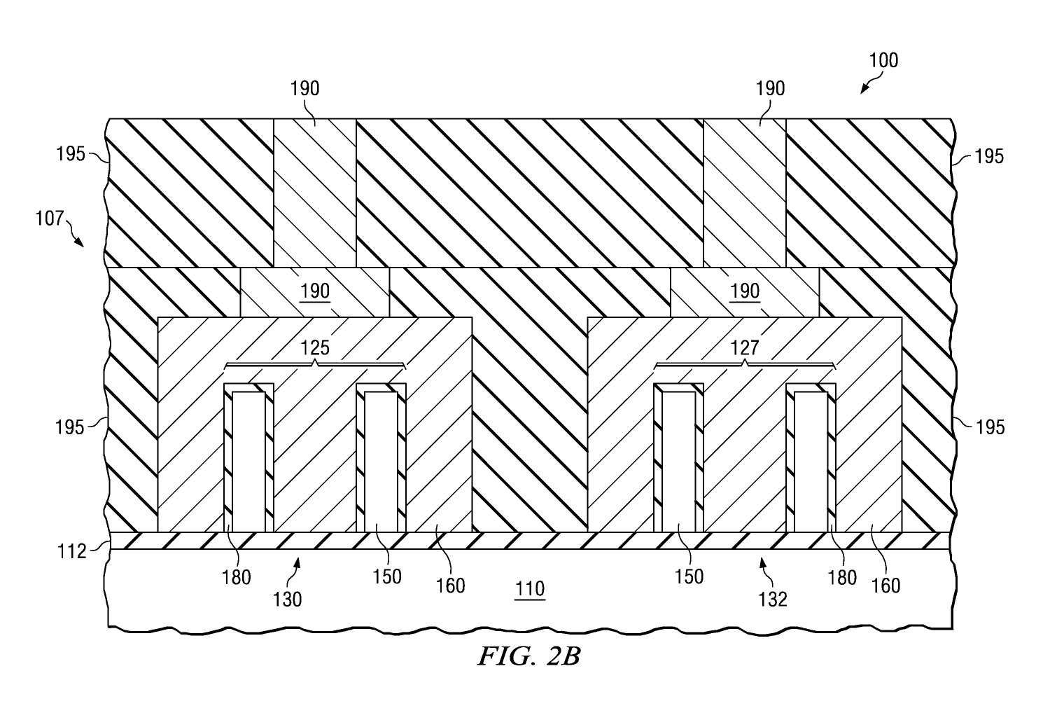

FIG. 1 shows a plan view of an example semiconductor device 100 of the disclosure, with its gate structures depicted transparently so that underlining structures can be seen. FIG. 2A presents a cross-sectional view of the same device 100 along view-line 2A-2A. FIG. 2B presents a cross-sectional view of the same device 100 along view-line 2B-2B. The semiconductor device 100 can be a SoC configured as an electrical communication device, such as a cellular phone, pager, Global Positioning System (GPS) locator, moving picture expert group audio layer-3 (MP3) player, or radio or television receiver.

The semiconductor device 100 comprises transistor devices (e.g., FETs) configured to perform specialized applications. The device 100 shown in FIGS. 1 and 2A-2B comprises a first transistor device 105 configured as a logic circuit (e.g., a microprocessor or digital signal processor) and a second transistor device 107 configured as a memory cell (e.g., static random access memory, SPAM). The first transistor device 105, located on a semiconductor substrate 110, has a first n-channel 115 and a first p-channel 117, in one or more of its first nMOS transistors 120 and one or more its first pMOS transistors 122, respectively. Similarly, the second transistor device 107, also on the substrate 110 (e.g., on a base oxide layer 112), has a second n-channel 125 and a second p-channel 127, in one or more second nMOS transistors 130 and one or more second pMOS transistors 132, respectively.

Each of the p-channels 117, 127 and n-channels 115, 125 and have a long lateral axis 135 that is aligned with a (110) orientation plane 140 of a silicon layer 150 (e.g., a patterned silicon layer) of the semiconductor substrate 110. Orienting the long lateral axis 135 in this direction improves hole mobility in the p-channels 117, 127 as compared to analogous p-channels aligned with a (100) orientation plane. E.g., the hole mobility can be about 2 times higher in a (110) orientation plane 140 as compared to a (100) orientation plane. However, electron mobility in the n-channels 115, 125 can be decreased (e.g., by about 2 times) as compared to analogous n-channels aligned with a (100) orientation plane.

To improve electron mobility, the first and second n-channels 115, 125 include the silicon layer 150 configured as strained silicon (e.g., biaxially tensile-strained silicon). The term strained silicon as used herein refers to a silicon layer that has been epitaxially grown on a material layer (e.g., a SiGe layer) whose lattice structure constant differs from that of unstrained silicon. E.g., the lattice structure constant for the material layer differs from unstrained silicon by at least about 1 percent. Some embodiments of the n-channels 115, 125 having a long axis 135 in the (110) orientation plane and composed of strained silicon have an electron mobility that is about 85 to 100 percent greater than an analogous n-channel composed of unstrained silicon.

The second p-channel 127 also includes the silicon layer 150. Some embodiments of the strained silicon can decrease the hole mobility by about 30 percent compared to an analogous p-channel composed of non-strained silicon. It is counter-intuitive that decreased hole mobility can be an advantage because a decreased mobility is normally viewed as undesirable. In this case, however, the second pMOS transistors 132 with such a p-channel 127, are used in the second transistor device 107 configured as a memory cell. The decreased hole mobility can be advantageous because it facilitates having a Beta ratio (i.e., a Iₒₙ(nMOS)/Iₒₙ(pMOS) ratio) that is desirable for a transistor device (e.g., the second transistor device 107) configured as an SRAM. In some cases a Beta ratio of about 2:1 or higher is desirable because a relatively low Iₒₙ(pMOS) is conducive to improving the write speed and write margin in certain memory circuits (e.g. SRAM) during their programming.

For the pMOS transistors 122 used in a transistor device (e.g., the first transistor device 105) configured as a logic circuit, however, a first p-channel 117 having an increased hole mobility can be desirable. An increased hole mobility promotes a higher Iₒₙ(pMoS), and this in turn, promotes a lower Beta ratio. To increase its hole mobility, the first p-channel 117 includes the silicon layer 150 configured as relaxed silicon. Strained silicon can be relaxed by implanting it with suitable atoms and annealing. E.g., in some embodiments, to form the relaxed silicon of the first p-channel 117, the silicon layer 150 comprising strained silicon is implanted with Si or Ge atoms and subjected to an anneal in the presence of H₂ gas to covert it to relaxed silicon. As a result, the Beta ratio for some embodiments of the transistor device 105 is about 2 or lower. Such a Beta ratio is desirable because this signifies that the pMOS transistors 122 can deliver about the same Iₒₙ as the nMOS transistor 120. Consequently, special manufacturing processes (e.g., to increase gate width) do not need to be performed to increase Iₒₙ(pMOS). This, in turn, helps to improve circuit speed by minimizing both the layout area for the pMOS transistors 122 and their gate capacitance.

To further enhance electron mobility, each of n-channels 115, 125 contact gate structures 160 that impart a tensile stress in the n-channels 115, 125. It is counter-intuitive to use gate structure made of tensile stress-producing material because this is traditionally thought to degrade the performance of transistors devices. Tensile stress-producing materials are typically not used as gate materials because of the unavailability of tensile producing materials having material properties that are suitable for gate electrodes in MOS transistors. Additionally, in some embodiments, the gate structures 160 comprises a mid-gap material (e.g., a material having a work function between silicon's the conduction band at about 4.1 eV and valence band of about 5.2 eV). A mid-gap material is desirable because the threshold voltages of fully-depleted transistors having thin channel regions are determined by gate-to-semiconductor work function differences, rather than the doping concentration of the semiconductor. Some embodiments of the gate structures 160 comprise TiN, TiSiN or other materials capable of imparting tensile stress in the n-channels 115, 125. In such embodiments, a tensile stress-producing gate structure 160 can improve electron mobility through the n-channels 115, 125 by about 80 percent (corresponding to an increase in Iₒₙ of about 20 percent) as compared an analogous device having a non-tensile-stressed gate structure. Moreover TiN and TiSiN are mid-gap materials having work functions that range from about 4.6 to 4.7 eV.

The manufacture of the device 100 is simplified if the same material and processing steps are used to manufacture the gate structures 160 for all of the transistors 120, 122, 130, 132. Therefore, in some embodiments, each of the p-channels 117, 127 also contact the tensile stress-producing gate structure 160. The gate structures 160 does not substantially change the hole mobility through the p-channels 117, 127, as compared to a gate structure comprising non-tensile stress producing material (e.g., the hole mobility is within about 10 percent for both types of gate structures). Therefore, in other embodiments, the gate structure contacting the p-channels 117, 127 can comprise a material that does not impart tensile stress in the p-channels 117, 127.

Consequently, for some embodiments, hole mobility in the first p-channel 117 is greater than hole mobility in said second p-channel 127, and electron mobility in the first and second n-channels are substantially equal to each other (e.g., within about 10 percent of each other). In some embodiments of the device 100, the first transistor device 105 (e.g., configured as a logic circuit) has a Beta ratio that is less than a Beta ratio of the second transistor device 107 (e.g., configured as a memory cell).

In some embodiments, at least one of the first or second transistor devices 105, 107 includes one or more multi-gate transistors 120, 122, 130, 132. The term multi-gate device as used herein refers to a transistor device comprising a channel that includes one or more raised portions (e.g. fins) that are enclosed on at least two sides by a gate structure. E.g., as illustrated in FIGS. 1 and 2A-2B, each of the n- or p-channels 115, 117 125, 127 in the multi-gate transistors 120, 122, 130, 132 include one or more of the silicon layers 150 configured (e.g., by patterning) as fins.

As further illustrated in FIGS. 2A-2E, the patterned silicon layers 150 are enclosed by the gate structures 160 on three sides in a tri-gate configuration. The tri-gate gate structure 160 comprises three gates, two on opposing sides of the channel regions 115, 117 and one (e.g., a top gate) adjacent to the two opposing gates. Double-gate is another form of multi-gate in which the gate structure comprises two gates, one each on opposing sides of the channel region. Those skilled in the art would be familiar with other configurations of multi-gate devices, such as omega-gates or pi-gates.

Multi-gate transistors can provide several functional advantages over single-gate planar transistor. E.g., Multi-gate transistors can provide superior electrical control over the channel as indicated by higher ratios of the on-state current (Iₒₙ) to sub-threshold current when the device is in the off-state (I_{off}). For instance, as compared to planar single-gate transistors.

Preferably, the multi-gate transistors 120, 122, 130, 132 are fully-depleted transistors. The term fully-depleted transistor, as used herein refers to a transistor whose channel region comprises a silicon layer 150 whose thickness 170 is equal to or less than a maximum depletion layer width in silicon during the transistor's operation. That is, during operation the silicon layer 150 of experiences full majority carrier depletion. In comparison, a partially depleted transistor comprises a silicon layer whose thickness is greater than the maximum depletion layer width during operation, and the transistor experiences only partial majority carrier depletion.

The strain engineering performed on the channels as disclosed above is preferable for fully-depleted transistors where the gate structures 160 comprises a mid-gap material, because, as discussed above, the threshold voltage is determined by gate-to-semiconductor work function differences. In contrast, for partially depleted transistors doping concentration of the semiconductor play the dominant role in setting the threshold voltage. Similar strain engineering is not done for certain partially depleted transistors because mid-gap materials are not suitable for setting the threshold voltage of such devices.

For some embodiments of the pMOS and nMOS multi-gate transistors 120, 122, 130, 132 configured as fully depleted transistors, the thickness 170 of the silicon layer 150, here configured as a fin, equals about 20 nanometers or less, and in some cases ranges from 20 to 10 nanometers. For some embodiments, a thickness 170 of less than 10 nanometers can result in a fragile fin that is prone to mechanical failure.

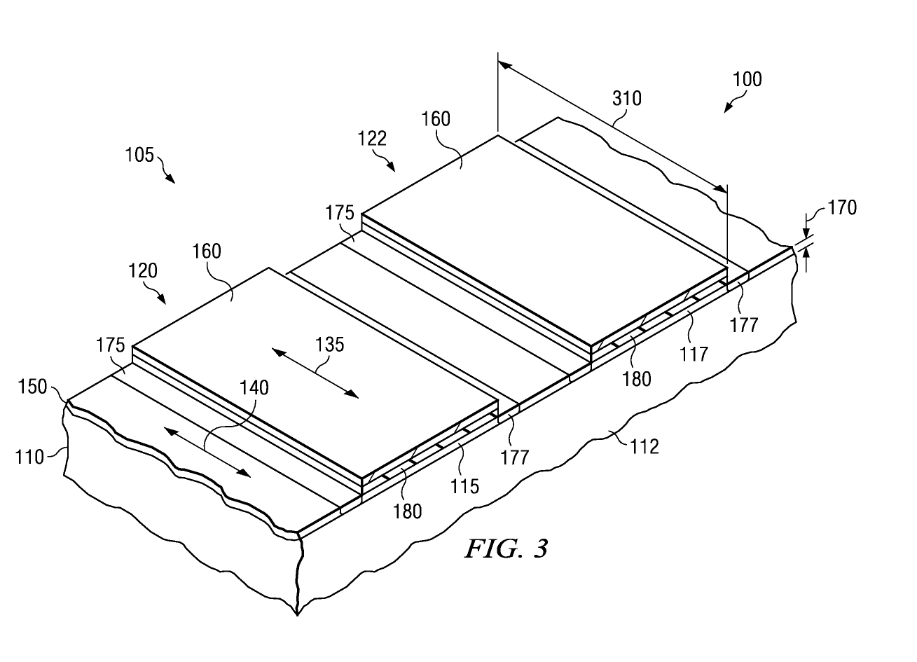

In still other embodiments of the device 100, at least one of the first or second transistor devices includes one or more single-gate planar transistors. FIG. 3 (numbered similarly to FIGS. 1-2B) shows a perspective view of a portion of an example first transistor device 105 that includes nMOS and pMOS transistors 120, 122 configured as single-gate planar transistors. For the reasons discussed above (e.g., ability to set the threshold voltage) preferred embodiments of nMOS and pMOS transistors 120, 122 are fully-depleted transistors.

The nMOS and pMOS transistors 120, 122 can comprise a silicon layer 150 having a thickness 170 of about 20 nanometers or less. The silicon layer 150 can have a long laterally axis 135 (e.g., along the width 310 of the planar gate structure 160) that is aligned with a (110) orientation plane of the silicon layer 150. The silicon layer 150 can be configured as strained silicon or relaxed silicon similar to that discussed above. The n-channel 115 can contact a planar gate structure 160 that imparts a tensile stress in the n-channel 115. In some embodiments both the n-channels and p-channels 115, 117 can contact the tensile stress-producing gate structure 160. A second transistor device (analogous to the second transistor device 107 shown in FIG. 1) could have nMOS and pMOS transistors that are similarly configured as single-gate planar transistors.

One skilled in the art would understand that the semiconductor device 100 can include other conventional transistor device components, including source and drain structures 175, 177, and a gate dielectric layer 180 (FIGS. 1 and 3). As further illustrated in FIG. 1, in some embodiments the source and drain structures 175, 177 can comprise portions of the patterned silicon layer that are not enclosed by the gate structure 160.

When the nMOS and pMOS transistors are configured as single-gate planar transistors (FIG. 3) their respective n- and p-channels 115, 117 can comprise portions of the strained silicon layer 150 that are bounded by source and drain structures 175, 177 also formed from the layer 150. E.g., source and drain dopants can be implanted into the portions of the strained silicon layer 150 that are adjacent to portions of layer 150 that are configured as one of the n- or p-channels 115, 117, followed by thermal anneal to form the source and drain structures 175, 177. A gate dielectric layer 180 can be formed between the n- and p-channels 115, 117 and overlying single-gate structure 160. The single-gate structure 160 can comprise tensile stress producing materials such as TiSiN and TiN.

The semiconductor device 100, configured as an integrated circuit, can further include one or more insulating layers 185 (e.g., silicon oxide or high-k dielectric materials) located over the transistor devices 105, 107. The device 100 can also include interconnects 190 (e.g., contacts, lines including single or dual damascene structures) formed in and over insulating layers 185 (e.g., pre-metal dielectric layer or interlayer dielectric layers). The interconnects 190 are configured to electrically couple the transistor devices 105, 107 to each other, or to other transistors, to make the device 100 operative.

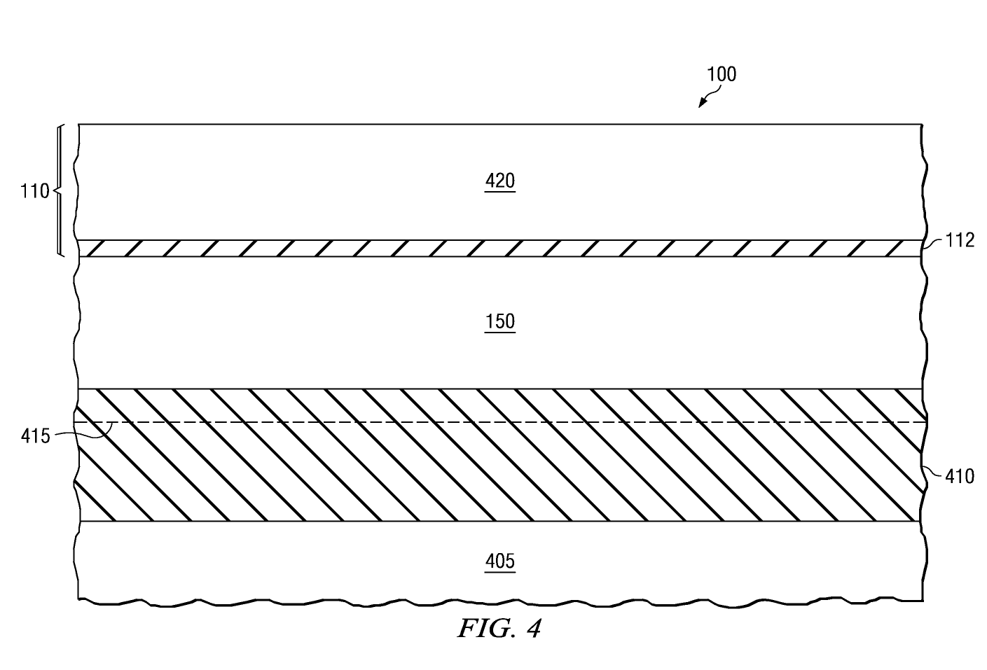

Another aspect of the invention is a method of manufacturing a semiconductor device. Any of the above-described embodiments of devices discussed in the context of FIGS. 1-3 can be manufactured by the method. FIGS. 4-8B show cross-sectional views of selected steps in example implementations of the method of manufacturing a semiconductor device 100 that includes multi-gate transistors (numbered similarly to FIGS. 1-2B). Analogous steps could be performed for a semiconductor device that includes single-gate planar transistors.

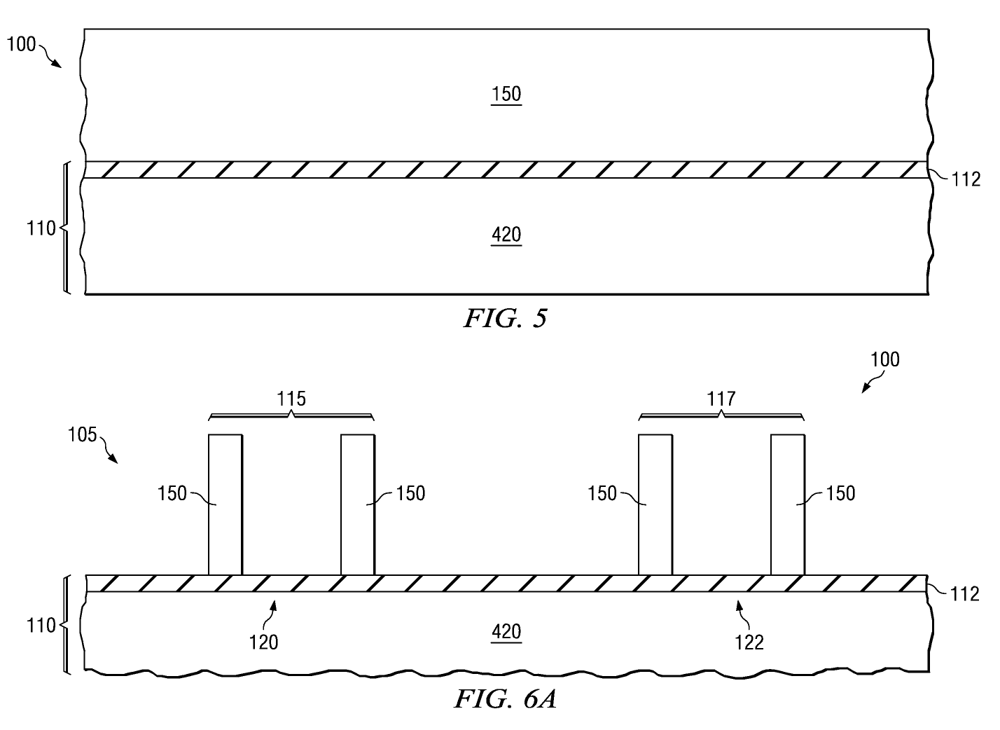

Manufacturing the semiconductor device 100 includes forming nMOS and pMOS transistors of first and second transistor devices, such as illustrated in FIGS. 4-8B. FIGS. 4 and 5 shows cross-sectional views (corresponding to either view line 2A-2A or 2B-2B of FIG. 1) of the semiconductor device 100 at selected stages in forming a strained silicon layer 150 on a substrate 405. FIG. 4 show the device 100 after epitaxially growing silicon on a silicon germanium (SiGe) layer 410 to form the strained silicon layer 150. The SiGe layer 410 can be deposited on a silicon wafer substrate 405 using chemical vapor deposition. Hydrogen (H₂⁺) can be implanted into the SiGe layer 410 to form a cleavage plane 415. FIG. 4 also shows the device 100 after bonding a semiconductor substrate 110 to the strained silicon layer 150. The substrate 110 can comprises a base oxide layer 112 and a base silicon layer 420, formed by e.g., subjecting a silicon wafer to a thermal oxidization progress.

FIG. 5 show the device 100 after cleaving the SiGe layer 410 shown in FIG. 4, along the cleavage plane 415, and removing any remaining portions of the SiGe layer 410, e.g., by conventional etching or chemical mechanical polishing processes. The resulting strained silicon layer 150 located on the base oxide layer 112 and base silicon layer 420, is substantially SiGe-free. One skilled in the art would understand that there are other ways to form a strained silicon layer than described in the above example.

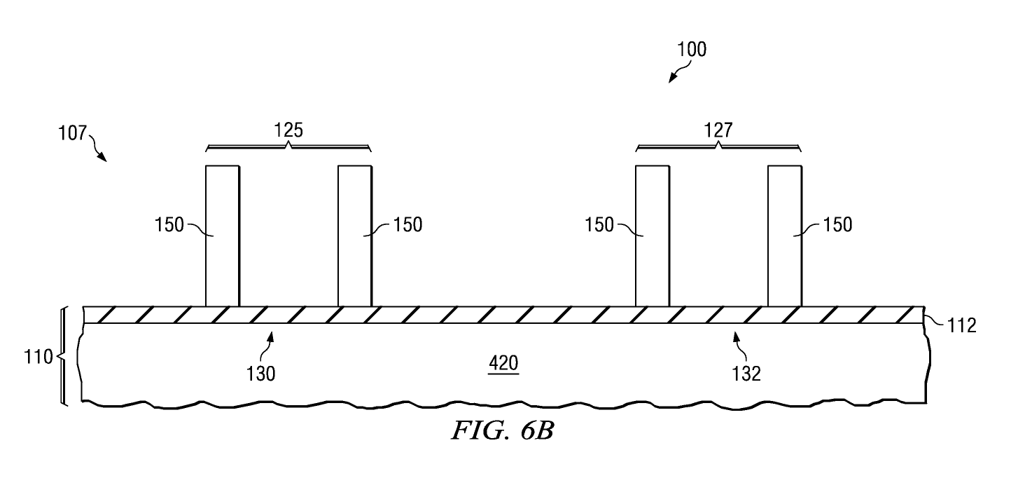

FIGS. 6A-6B show cross-sectional views of the device 100 (corresponding to view line 2A-2A or 2B-2B of FIG. 1, respectively) after forming n-channels 115, 125 and p-channels 117, 127 of the nMOS and PMOS transistors 120, 122, 130, 132 from the strained silicon layer 150. E.g., the strained silicon layer 150 of FIG. 5A-5B can be patterned using conventional photolithographic and etching processes to form patterned strained silicon layers 150 (FIG. 6A-6B) that are configured as fins of multi-gate devices 120, 122, 130, 132. The channels 115, 117, 125, 127 are formed so that their long lateral axis 135 (FIG. 1) is aligned with a (110) orientation plane 140 of the strained silicon layer 150. In other embodiments, however, such as when the nMOS and pMOS transistors 120, 122, 130, 132 are single-gate planar transistors, the strained silicon layer 150 is left intact. E.g., as discussed above in the context of FIG. 3, source and drain structures can be formed adjacent to portions of the strained silicon layer configured as one of the n- or p-channels, to thereby define the channel.

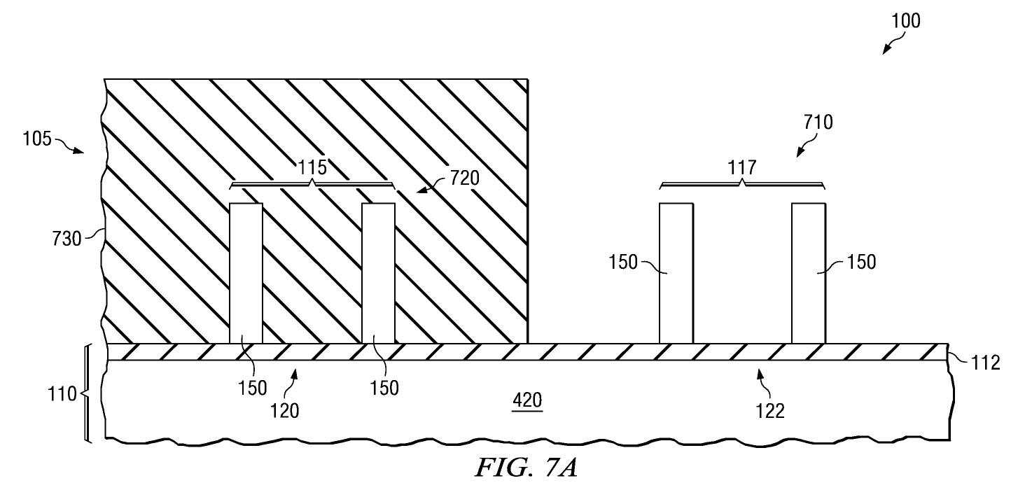

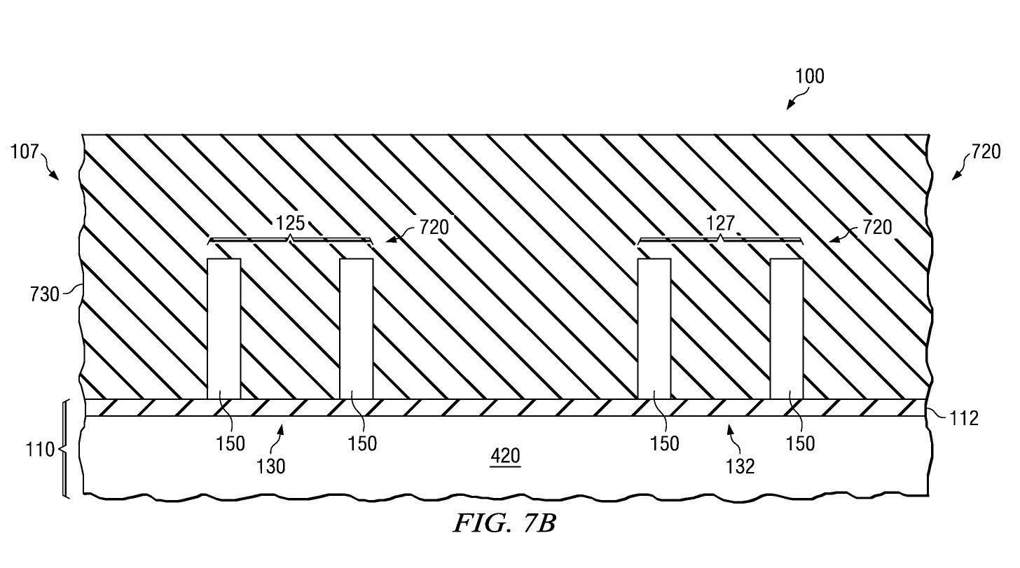

FIG. 7A show the device 100 in FIG. 6A after converting a portion 710 of the strained silicon layer 150 for said p-channels of said first transistor device to relaxed silicon. For devices 100 having multi-gate transistors, as shown in FIG. 7A, the converted portion 710 of strained silicon corresponds to the patterned strained silicon layer 150 that is configured as fins for the p-channel 117 of the first transistor device 105. As discussed above, this is desirable when the first transistor device 105 is configured as a logic circuit. For devices 100 having single-gate planar pMOS transistors, the converted portion of strained silicon can correspond to unpatterned layer of strained silicon layer 150 that serves as the p-channel.

Converting strained silicon to relaxed silicon can be achieved by implanting the appropriate dopants in the channel 117 followed by a high temperature thermal anneal. E.g., in some embodiments, converting includes implanting Si or Ge into the desired portion of the strained silicon. Implantation can be followed by a thermal anneal comprising, e.g., a temperature ranging from about 600 to 900° C. in the presence of about 15 to 600 Torr of H₂, for about 5 minutes. Performing the thermal anneal in the presence of H₂ gas is desirable because Si migrates to the lowest energy state in the presence of H₂, thereby facilitating the formation of unstrained Si.

As shown in FIGS. 7A and 7E, while converting the portion 710 of the strained silicon layer 150 to relaxed silicon it is desirable to prevent remaining portions of the strain silicon layer 150 from being similarly converted. E.g., while converting the portion 710, remaining portions 720 of the strained silicon layer 150 are covered with a mask layer 730 (e.g., a SiN hard mask) to prevent the layer's 150 implantation with Si or Ge, or exposure to H₂ gas (FIGS. 7A-B). Consequently, the p-channels 127 of the second transistor device 100 and the n-channels 115, 117 of the first and second transistor devices 105, 107 include the remaining portion 720 of strained silicon layer 150.

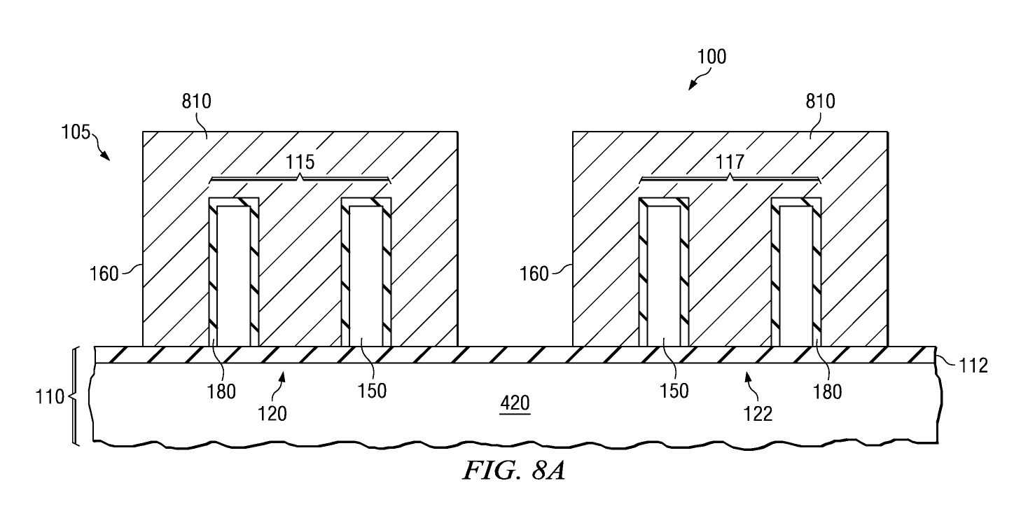

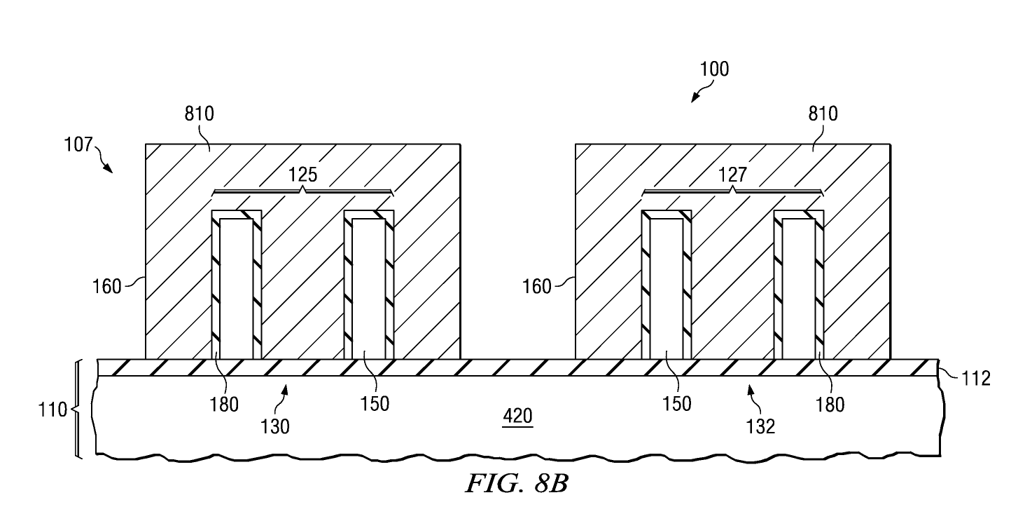

FIGS. 8A-8E shows the device 100 of FIGS. 7A and 7B after removing the mask layer 730, and forming gate structures 160 on each of the n-channels 115, 125 and p-channels 117, 127. The gate structures 160 on the n-channels 115, 125 impart a tensile stress in the n-channels 115, 125. E.g., forming the gate structure 160 on the n-channels 115, 125 can include forming a gate electrode 810. Forming the gate electrode 810 includes depositing a metal layer, such as TiSiN or TiN, over the n-channels 115, 125. The gate structures 160 on the p-channels 117, 127 can be made of the same or different metal as used for the gate structure 160 on the n-channels 115, 125. E.g., a metal layer having TiSiN or TiN can also be deposited over the p-channels 117, 127. In some embodiments, it is desirable to deposit the gate electrode 810 using a technique that can provide a uniform metal layer on the channels 115, 117, 125, 127 that are configured as fins. Such techniques include chemical vapor deposition (CVD) or atomic layer deposition. However, other deposition techniques such as physical vapor deposition can also be used.

Forming the gate structures 160 can also include depositing a gate dielectric layer 180 on the n- and p-channels 115, 117, 125, 127, before forming the gate electrode 810. E.g., the dielectric layer 180 can comprise silicon dioxide (SiO₂) grown on the channels 115, 117, 125, 127, configured as fins, by thermal oxidation, or a high-k dielectric material deposited by low-pressure or plasma-enhanced CVD. In some preferred embodiments, to reduce current leakage, nitrogen is included in the SiO₂ dielectric layer 820 by a plasma nitrided oxidation process.

The manufacture of the device 100 can also comprise forming insulating layers 185 over the first and second transistor devices 105, 107 and after forming interconnects 190 in or on the insulating layers 185, the interconnects 190 contacting the first and second transistor devices 105, 107 (FIGS. 2A and 2B).

Those skilled in the art to which the disclosure relates will appreciate that other and further additions, deletions, substitutions, and modifications may be made to the described example embodiments, without departing from the disclosure.

What is claimed is:

1. A semiconductor device, comprising:
a first transistor device on a semiconductor substrate, said first transistor device having a first n-channel and a first p-channel; and
a second transistor device on said semiconductor substrate, said second transistor device having a second n-channel and a second p-channel, wherein:
each of said p-channels and said n-channels and have a long lateral axis that is aligned with a (110) orientation plane of a silicon layer of said semiconductor substrate,
said second p-channel and said first and said second n-channels include a silicon layer configured as strained silicon,
said first p-channel includes said silicon layer configured as relaxed silicon, and
each of said n-channels contact gate structures that impart a tensile stress in said n-channels.

2. The device of claim 1, wherein at least one of said first or second transistor devices includes one or more single-gate planar transistors, wherein said single-gate planar transistors are fully-depleted transistors.

3. The device of claim 1, wherein at least one of said first or second transistor devices includes one or more multi-gate transistors, wherein said multi-gate transistors are fully-depleted transistors.

4. The device of claim 3, wherein each of said n- or p-channels in said multigate transistors include one or more of said silicon layers that are configured as fins and that are enclosed by said gate structure.

5. The device of claim 1, wherein each of said p-channels contact said gate structures.

6. The device of claim 1, wherein said gate structure includes a mid-gap material.

7. The device of claim 1, wherein said silicon layer of said first p-channel is implanted with Si or Ge and subjected to an anneal in the presence of H₂ gas.

8. The device of claim 1, wherein said first transistor device includes first nMOS and pMOS transistors in a logic circuit.

9. The device of claim 1, wherein said second transistor device includes second nMOS and pMOS transistors in a memory circuit.

10. The device of claim 1, wherein hole mobility in said first p-channel is greater than hole mobility in said second p-channel, and electron mobility in said first and second n-channels are substantially equal to each other.

11. The device of claim 1, wherein said first transistor device has a Beta ratio that is less than a Beta ratio of said second transistor device.

12. A semiconductor device, comprising:
a first multi-gate device on a semiconductor substrate, said first multi-gate device having a first n-channel and a first p-channel;
a second multi-gate device on said semiconductor substrate, said second multi-gate device having a second n-channel and a second p-channel;
insulating layers located over said first and second multi-gate devices; and
interconnects in or on said insulating layers, said interconnects contacting said first and second multi-gate devices, wherein:
each of said p-channels and said n-channels and have a long lateral axis that is aligned with a (110) orientation plane of a patterned silicon layer of said semiconductor substrate that is configured as fins,
said first p-channel include said patterned silicon layer configured as relaxed silicon,
said second p-channel and said first n-channels and said second n-channels include said patterned silicon layer configured as strained silicon, and
each of said n-channels contact gate structures that impart a tensile stress in said n-channel.

13. A method of manufacturing a semiconductor device, comprising:
forming nMOS and pMOS transistors of first and second transistor devices, including:
forming a strained silicon layer on a semiconductor substrate;
forming n-channels and p-channels of said nMOS and said pMOS transistors from said strained silicon layer, such that a long lateral axis of said channels is aligned with a (110) orientation plane of said strained silicon layer;
converting a portion of said strained silicon layer for said p-channels of said first transistor device to a relaxed silicon layer, wherein said p-channels of said second transistor device and said n-channels of said first and said second transistor devices include a remaining portion of said strained silicon layer; and
forming gate structures on each of said n-channels and p-channels, wherein said gate structures impart a tensile stress in said n-channels.

14. The method of claim 13, wherein forming said strained silicon layer includes epitaxally growing said silicon layer on a silicon germanium layer and then removing said silicon germanium layer.

15. The method of claim 13, wherein said nMOS and PMOS transistors are multi-gate transistors and forming said n-channels and p-channels includes patterning said strained silicon layer to form one or more fins.

16. The method of claim 13, wherein said nMOS and PMOS transistors are single-gate planar transistors and forming said n-channels and said n-channels includes forming source and drain structures adjacent to portions of said strained silicon layer configured as one of said n-channels or said p-channels.

17. The method of claim 13, wherein said converting includes implanting Si or Ge into said portion of said strained silicon layer while masking said remaining portion of said strained silicon.

18. The method of claim 13, wherein said converting includes exposing said portion to an H₂ atmosphere and high temperature anneal while masking said remaining portion of said strained silicon.

19. The method of claim 13, wherein forming said gate structures includes forming a gate electrode including depositing a metal layer having TiSiN or TiN over said n-channel and p-channel.

20. A method of manufacturing a semiconductor devices comprising:
forming nMOS and pMOS transistors of first and second multi-gate devices, including:
forming a strained silicon layer on a semiconductor substrate;
patterning said strained silicon layer to form n-channels and p-channels of said nMOS and said pMOS transistors that are configured as fins and such that a long lateral axis of said channels is aligned with a (110) orientation plane of said strained silicon layer;
converting a portion of said strained silicon layer for said p-channels of said first multi-gate device to a relaxed silicon layer, wherein said p-channels of said second multi-gate device and said n-channels of said first and said second multi-gate devices include a remaining portion of said strained silicon; and
forming gate structures on each of said n-channels and p-channels, wherein said gate structures impart a tensile stress in said n-channels and p-channels;
forming insulating layers over said first and second transistor devices; and
forming interconnects in or on said insulating layers, said interconnects contacting said first and second multi-gate devices.
